(19) United States
(12) Patent Application Publication
(10) Pub. No.: US 2004/0150054 A1
(43) Pub. Date: Aug. 5, 2004

(54) Semiconductor integrated circuit including fuse device and method for manufacturing the same

(75) Inventor: Shinji Hirano, Mihama-ku (JP)

Correspondence Address: OLIFF & BERRIDGE, PLC, P.O. BOX 19928, ALEXANDRIA, VA, 22320, US

(73) Assignee: KAWASAKI MICROELECTRONICS, INC., Mihama-ku (JP)

(21) Appl. No.: 10/762,474

(22) Filed: Jan. 23, 2004

(30) Foreign Application Priority Data
Jan. 29, 2003 (JP) 2003-019865

(51) Int. Cl. H01L 21/8238; H01L 29/76

(52) U.S. Cl. 257/371; 438/223; 257/379; 438/210

(57) ABSTRACT

A semiconductor integrated circuit including a fuse device, and methods for manufacturing a semiconductor integrated circuit, are disclosed. The fuse device, which is programmable by the intrusion of a flowable metal from an electrode into a junction formed in a semiconductor region, has a high initial yield and a low resistance after being programmed. The contact hole of the fuse device has a columnar insulator region having a height lower than the top end of the contact hole. The columnar insulator region limits the contact area between the electrode and the semiconductor region of the fuse device. The electrode has an excellent coverage at the upper portion of the contact hole.

### BACKGROUND OF THE INVENTION

1. Field of Invention

This invention relates to a semiconductor integrated circuit having a PN-junction destruction type fuse device and a method for manufacturing the same.

2. Description of Related Art

In one known method for adjusting a circuit parameter of a semiconductor integrated circuit, such as a resistance, a fuse device is used. A fuse device is non-conductive in an initial state when the manufacturing process is completed, but can be changed or programmed to a permanently conductive state by application of a breakdown voltage.

One type of fuse device is a PN-junction destruction type fuse device. The PN junction is formed in a semiconductor region, i.e., in a surface region of a semiconductor (silicon) substrate or in a polycrystalline silicon layer provided over a semiconductor substrate. Metal atoms are forced to enter the semiconductor region from an electrode through the application of an electric field or of heat. Thereby, the junction is destroyed by a reaction between the metal atoms and the semiconductor (silicon) atoms in the junction region, and a conductive state is established.

FIG. 5 is a schematic diagram of an example of a trimming circuit to adjust the resistance by using Zener zap diodes, which are one type of fuse device. The trimming circuit 60 shown in FIG. 5 is provided with a plurality of resistor elements R1 to Rn serially connected between a terminal A and a terminal B, and a plurality of Zener zap diodes D1 to Dn connected in parallel to the resistor elements R1 to Rn, respectively. A plurality of pads (electrodes) P1 to Pn+1 are connected to both ends of the resistor elements R1 to Rn, respectively.

In order to adjust the resistance between the terminals A and B in the trimming circuit 60, a reverse voltage (reverse bias) exceeding the breakdown voltage of the Zener zap diode is applied between specific pads among the pads P1 to Pn+1. Consequently, the junction of the one of the Zener zap diodes D1 to Dn disposed between the specific pads to which the reverse bias is applied are short-circuited and destroyed. Thereby, the resistance between these specific pads is reduced. In this manner, the total resistance between the terminal A and the terminal B is adjusted.

For example, when a reverse bias is applied between pad 2 and pad 3, in the Zener zap diode D2, aluminum (Al) atoms in an anode electrode, which is negative relative to a cathode electrode, flow to enter a semiconductor region in which the Zener zap diode is formed. The Al atoms thus entered and silicon atoms in the semiconductor region react to form a filament made of an alloy of aluminum and silicon, so that the junction is short-circuited and destroyed. Consequently, the reverse resistance of the Zener zap diode D2 is reduced from an order of giga ohms to 15 ohms or less. That is, the Zener zap diode D2 serving as a fuse device is programmed by being changed from a nonconductive state to a conductive state.

As such, trimming of the circuit parameter (resistance) is carried out. Metal, which flows into the semiconductor region in which the fuse device is formed and destroys the junction, such as aluminum as described above, is referred to as a flowable metal in this specification.

In general, the process rule of semiconductor devices becomes finer and finer to meet the demand for higher integration. The technology for forming the contact must be changed as the process rule becomes finer.

Previously, the electrode of the fuse device is formed from a film of AlSi alloy, which primarily contains Al and, for example, about 1 weight percent of Si. As has been explained, aluminum is capable of entering the junction to cause a short-circuit and destruction of the junction.

Generally, an interlayer insulating film is formed on a semiconductor substrate provided with fuse devices and other devices, such as, for example, transistors, and contact holes are formed in specific locations in the interlayer insulator film as necessary. An AlSi film is deposited in the contact holes and on the interlayer insulating film, and patterning is carried out so as to form electrodes for different devices and, furthermore, to form wirings connecting the plurality of devices to each other.

However, when the contact hole becomes smaller, it is difficult to deposit the AlSi film therein. Consequently, it has become common usage to fill the contact hole with a tungsten plug.

Furthermore, Si atoms contained in the AlSi alloy film form nodules during thermal steps carried out during the manufacturing process after the electrode is formed. As a result, the reliability of fine wirings is degraded. Consequently, it has become common to use AlCu alloy, which is an Al alloy containing, for example, about 0.5 weight percent of Cu and no Si, as the material for forming electrodes and wirings.

However, when a reverse bias is applied in order to cause destruction of a Zener zap diode while the tungsten plug is present in the contact hole, movement of aluminum atoms from the anode electrode into the semiconductor region is hindered. Therefore, a problem arises in that the destruction of the junction cannot be carried out.

It could be possible to keep the size of the contact hole of the fuse device sufficiently large and avoid using the tungsten plug while making other devices smaller by utilizing the tungsten plug. However, when the electrode made of the AlCu film is brought into direct contact with the semiconductor region for forming the fuse device, an initial failure occurs. That is, the fuse device becomes conductive when the manufacturing process is completed and before applying the reverse voltage to change it to the conductive state.

This initial failure results from a spike generated during thermal steps carried out in the manufacturing process after the electrode is formed. That is, silicon atoms in the semiconductor region migrate into the AlCu electrode through the interface between the AlCu electrode and the semiconductor region, and Al atoms in the AlCu electrode migrate into voids, which are formed by the movement of Si atoms into the AlCu electrode, in the semiconductor region.

When the AlSi alloy is used as the material for the electrode, Si is added beforehand to the AlSi alloy used for forming the electrode. The amount of Si exceeds the solid solubility, which is the maximum amount of Si capable of dissolving into Al at the maximum temperature (about 400° C.) of the heat treatments after electrode formation. Therefore, no spike is generated.

However, when the electrode is formed from the AlCu alloy containing no Si, spikes are generated, and a problem of low initial yield arises.

Technologies proposed in, for example, Japanese Unexamined Patent Application Publication No. A-2000-340750 (first reference) and U.S. Pat. No. 5,019,878 (second reference) are previously known.

In the first reference, a contact hole (a second contact hole) for a Zener zap diode is formed to have a width larger than the width of a contact hole (a first contact hole) for other devices. A tungsten film is formed to be thinner than one-half of the width of the second contact hole. The tungsten film is etched back so as to form a tungsten plug in the first contact hole and to expose the surface of the silicon substrate at the bottom of the second contact hole. An anode electrode is formed in the second contact hole from aluminum or an aluminum alloy film.

However, in the method described in the first reference, when an amount of etch back adequate for exposing the bottom of the second contact hole is ensured, the upper portion of the tungsten plug of the first contact hole is also etched and, thereby, the filling property is degraded. Furthermore, no consideration is given to the problem of the low initial yield due to the generation of spikes in the case where the electrode is formed from aluminum or an aluminum alloy containing no Si.

The second reference discloses a method in which a MOSFET is used as a fuse device. A programming voltage of equal to or higher than the breakdown voltage is applied between the drain region and the source region, and titanium silicide formed as the electrode material is forced to flow. Consequently, a conductive filament connecting between the drain region and the source region is formed.

However, no consideration is given to the problems arising when the tungsten plug is filled in the contact hole.

### SUMMARY OF THE INVENTION

It is an object of this invention to overcome the above-described problems based on the previously known technologies. It is a further object of this invention to provide a semiconductor integrated circuit capable of sufficiently lowering the post-programming resistance of a fuse device after it is programmed while utilizing tungsten plugs for other devices, and capable of achieving a high initial yield, and to provide a method for manufacturing the same.

In order to achieve the above-described objects, this invention provides, in embodiments, a method for manufacturing a semiconductor integrated circuit including providing a semiconductor substrate having a fuse device present at least partly in a semiconductor region on or over a surface of the semiconductor substrate, and forming an interlayer insulating film having a top surface over the surface of the semiconductor substrate. The method further includes forming a contact hole in the interlayer insulating film over the semiconductor region such that a columnar insulator region having a top end lower than the top surface of the interlayer insulating film is formed at a central portion of the contact hole, and forming an electrode in the contact hole such that the electrode contacts the semiconductor region at a periphery of a bottom of the contact hole where the columnar insulator region is not formed.

This invention also provides, in embodiments, a semiconductor integrated circuit including a semiconductor substrate having a fuse device present at least partly in a semiconductor region on a surface of the semiconductor substrate, an interlayer insulating film covering the surface of the semiconductor substrate, the interlayer insulating film having a top surface and a contact hole over the semiconductor region, a central portion of the contact hole having a columnar insulator region with a top end lower than the top surface of the interlayer insulating film. The semiconductor integrated circuit further includes an electrode that contacts the semiconductor region at a periphery of a bottom of the contact hole.

This invention also provides, in embodiments, a method of manufacturing a semiconductor integrated circuit including providing a semiconductor substrate having a fuse device present at least partly in a semiconductor region on or over a surface of the semiconductor substrate, forming an interlayer insulating film having a top surface over the surface of the semiconductor substrate, and forming a contact hole in the interlayer insulating film over the semiconductor region. The method further includes forming a film of an electrode material in the contact hole to form an electrode that contacts the semiconductor region at a bottom of the contact hole. The forming of the contact hole and the forming of the film of electrode material in the contact hole further includes reducing a contact area between the electrode and the semiconductor region by forming a columnar insulator region at a central portion of the contact hole and increasing an amount of the electrode material in the contact hole by making a top end of the columnar insulator region lower than the top surface of the interlayer insulating film.

These and other objects, advantages and salient features of the invention are described in or are apparent from the following detailed description of exemplary embodiments.

### BRIEF DESCRIPTION OF THE DRAWINGS

FIG. 1 is a schematic sectional diagram of a semiconductor integrated circuit according to an embodiment of this invention.

FIGS. 2A-2D are schematic sectional diagrams illustrating steps of a method for manufacturing a semiconductor integrated circuit according to an embodiment of this invention.

FIGS. 3A-3B are schematic sectional diagrams illustrating steps of the method for manufacturing the semiconductor integrated circuit according to the embodiment of this invention, following the step shown in FIG. 2D.

FIGS. 4A-4C are schematic plan views showing the shape of a first contact hole according to an embodiment of this invention.

FIG. 5 is a schematic diagram of an example of a trimming circuit that adjusts the resistance.

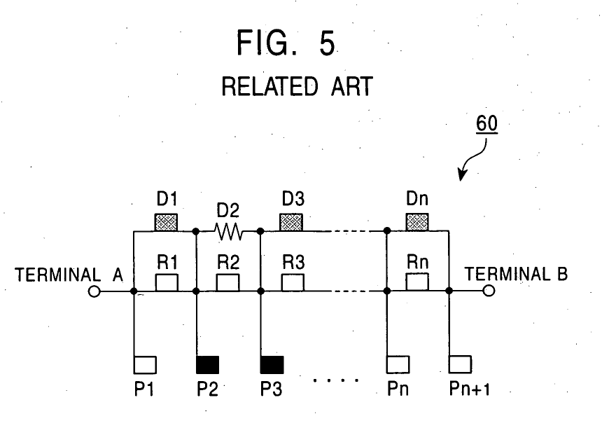

### DETAILED DESCRIPTION OF PREFERRED EMBODIMENTS

This invention was first described in Japanese Patent Application No. 2003-19865, which is incorporated herein by reference in its entirety.

A semiconductor device and a method for manufacturing the same according to this invention will be described below in detail based on an exemplary embodiment shown in the drawings.

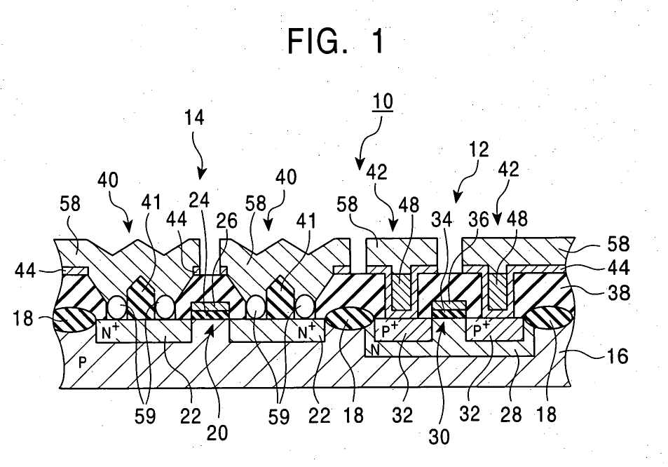

FIG. 1 is a schematic sectional diagram of a semiconductor integrated circuit according to an embodiment of this invention. In the semiconductor integrated circuit 10 shown in the drawing, the left side is an N-type MOS transistor (hereafter referred to as NMOS) 14 used as a fuse device.

The right side in the drawing is a P-type MOS transistor (hereafter referred to as PMOS) 12 used as an element for constructing circuitry of the semiconductor integrated circuit. It is clear that a plurality of PMOS as well as NMOS are used to construct various circuitry of the integrated circuit. The PMOS 12 is shown as an example of semiconductor devices other than the NMOS 14 that is used as a fuse.

Respective device formation regions for the PMOS 12 and the NMOS 14 are arranged on the surface of a semiconductor substrate 16. Each device formation region is isolated from each other with a field isolation film 18 formed by a LOCOS (Local Oxidation of Silicon) method.

In the NMOS 14 used as a fuse device, source and drain regions (N⁺-type diffusion regions) 22 are formed on either side of a channel region 20. These regions are formed in the device formation region on the surface of a P-type semiconductor substrate 16 or in a P well region provided on the surface of a semiconductor substrate. A gate electrode 26 is provided over the channel region 20 with a gate dielectric film 24 therebetween.

An interlayer insulating film 38 is formed over the entire surface of the semiconductor substrate 16 on which the device formation regions are provided. Contact holes 40 are formed in the interlayer insulating film 38 at portions located over the source and drain regions 22 of the NMOS 14.

A columnar insulator region 41 having a height lower than the top of the contact hole 40 (the top surface of the interlayer insulating film 38) is provided in the central portion of the contact hole 40. Furthermore, the contour of the contact hole 40 and the head of the columnar insulator region 41 are tapered.

A barrier metal layer 44 is provided on specific portions of the interlayer insulating film 38. An electrode 58, made of an AlCu alloy, is formed inside the contact holes 40, and over the barrier metal layer 44 on the interlayer insulating film 38.

The electrode 58 is in contact with the source or drain region 22 at the bottom of the contact holes 40 and, thereby, is connected to the NMOS 14. However, because the insulator region 41 is present in the central portion, the electrode 58 contacts the source or drain region 22 only at the peripheral portion of the bottom of the contact hole 40 where the insulator layer 41 is not present. That is, the contact is made only in a region having an area significantly smaller than the area of the entire contact hole 40 because of the space occupied by the insulator 41.

The bottom of the contact hole 40 has a significantly large aspect ratio (ratio of the height to the width) of the aperture, because of the presence of the columnar insulator region 41. Consequently, as shown in FIG. 1, a void 59, in which no electrode material is present, is formed at the bottom of the contact hole 40 between the insulator region 41 and the sidewall of the hole 40.

It is to be noted that in eachcontact hole 40, a ring-shaped void 59 is formed around the insulator region 41. That is, FIG. 1 shows two different cross-sections of the same void 59 formed in each contact hole 40.

On the other hand, in the upper portion of the contact hole 40, the height of the columnar insulating region is lower than the top end of the contact hole. Furthermore, the contour of the contact hole 40 and the head of the columnar insulator region 41 are tapered. Consequently, the AlCu film constituting the electrode 58 is formed with an excellent coverage, that is, a large amount of AlCu serving as the electrode material is present in the upper portion of the contact hole 40.

In the initial state before programming by the application of a reverse bias, the NMOS 14 is in a nonconductive state. That is, the resistance between the drain and the source of the NMOS 14, measured with the gate electrode and the source region at the same potential, shows a significantly high resistance, on the order of giga-ohms.

In order to program this NMOS 14, a high voltage, which is positive relative to the source region, is applied to the drain region. Simultaneously, an appropriate voltage is also applied to the gate electrode, if necessary. As a result, the junction between the drain region and the channel region breaks down.

Therefore, when correlated with the case of the conventional Zener zap diode previously described, the drain electrode corresponds to the cathode electrode, and the source electrode corresponds to the anode electrode.

Because of the breakdown due to the application of the reverse bias, a large reverse current flows from the drain region of the NMOS 14 toward the source region. The reverse current generates an electron flow from the source region to the drain region. Pushed by the force generated by the electron flow, atoms of the flowable metal in the source electrode, that is, Al in this embodiment, flow to enter the semiconductor region, i.e., the device formation region on the surface of the semiconductor substrate 16, from the source region 22. The atoms of the flowable metal pass through the source region 22 and the channel region 20, and enter the junction region between the drain region 22 and the channel region 20. Then, silicon atoms in the junction region react with the atoms of flowable metal and, consequently, the junction is permanently destroyed.

In this manner, the junction is short-circuited and destroyed. Thereby, the NMOS 14 is programmed by being changed from a nonconductive state to a conductive state.

When the application of the voltage is further continued, the conductive filament formed by the reaction between the atoms of flowable metal and silicon atoms finally short-circuits between the source electrode and the drain electrode. Consequently, a conductive state, with a significantly low resistance, is established.

As shown in FIG. 1, in the semiconductor device 10 of this embodiment, the electrodes 58, made of an Al alloy containing no Si, are in contact with the source and drain regions 22 of the NMOS 14. In these contact regions between the Al alloy containing no Si and the semiconductor regions, i.e., portions of the device formation region on the surface of the semiconductor substrate 16, there is the possibility that Al atoms enter the semiconductor regions below the contact surfaces during thermal steps carried out during the manufacturing process. If the Al atoms enter the semiconductor region, a spike is generated and, therefore, causes an initial failure.

The generation of spikes can be suppressed by decreasing the contact area between the electrode and the semiconductor region. However, if the size of the contact hole 40 is simply decreased to reduce the contact area, the amount of AlCu alloy in the contact hole is also decreased. As a result, due to the movement of Al atoms during the application of the reverse bias, problems may arise in that, for example, disconnection of the electrode may occur in the contact hole. Or, because an adequate amount of Al (flowable metal) cannot be supplied to the fuse device, the growth of filament becomes inadequate. As a result, the resistance of the fuse device after the destruction cannot be adequately reduced.

In the semiconductor device 10 of the embodiment shown in FIG. 1, the columnar insulator region 41 decreases the contact area at the bottom of the contact hole 40. Therefore, generation of the spike is prevented, or significantly suppressed. In addition, the height of the columnar insulator region 41 is lowered, and the head thereof and the contour of the contact hole 40 are tapered. Consequently, the amount of AlCu alloy in the upper portion of the contact hole 40 is increased. As a result, occurrence of electrode disconnection during the programming is prevented, and the resistance of the fuse device can be lowered adequately.

Furthermore, in the semiconductor integrated circuit 10 of the embodiment shown in FIG. 1, a void 59 is formed at the bottom of the contact hole 40 because of the existence of the columnar insulator region 41. The presence of the void decreases the amount of Al atoms present in the vicinity of the interface between the electrode 58 and the source or drain regions 22. As a result, the generation of spike is further diminished or suppressed.

Even when the void 59 is present when the manufacturing process is completed, the filament is adequately formed. Because large amounts of AlCu alloy exist in the upper portion of the contact hole 40, sufficient amounts of Al (flowable metal) atoms are supplied from this portion during the application of the reverse bias.

However, formation of the void 59 in the bottom portion of the contact hole 40 is not always necessary in a semiconductor integrated circuit according to this invention. When simply reducing the contact area by means of the insulator region 41 can suppress the generation of spike and ensure a desired initial yield, the formation of the void 59 is not necessary.

On the other hand, in the PMOS 12 used as an element to construct various circuitry of the semiconductor integrated circuit, source and drain regions (P⁺-type diffusion regions) 32 are formed on either side of a channel region 30. These regions are formed in a device formation region in an N well region 28 provided in the surface of the P-type silicon substrate 16. Likewise, a gate electrode 36 is formed on the channel region 30 with a gate dielectric film 34 therebetween.

Contact holes 42 are formed in the interlayer insulating film 38 over the source and drain regions 32 of the PMOS 12. A barrier metal layer 44 is provided in the contact holes 42 and in predetermined locations on the interlayer insulating film 38. A plug 48 made of a refractory metal (high-melting point metal) is formed in the contact hole 42. An electrode 58 made of an AlCu alloy film is formed over the plug 48 in the contact hole 42 and over the barrier metal layer 44. Electrodes 30 are connected to the source and drain regions 32 of the PMOS 12 with the plugs 48 therebetween.

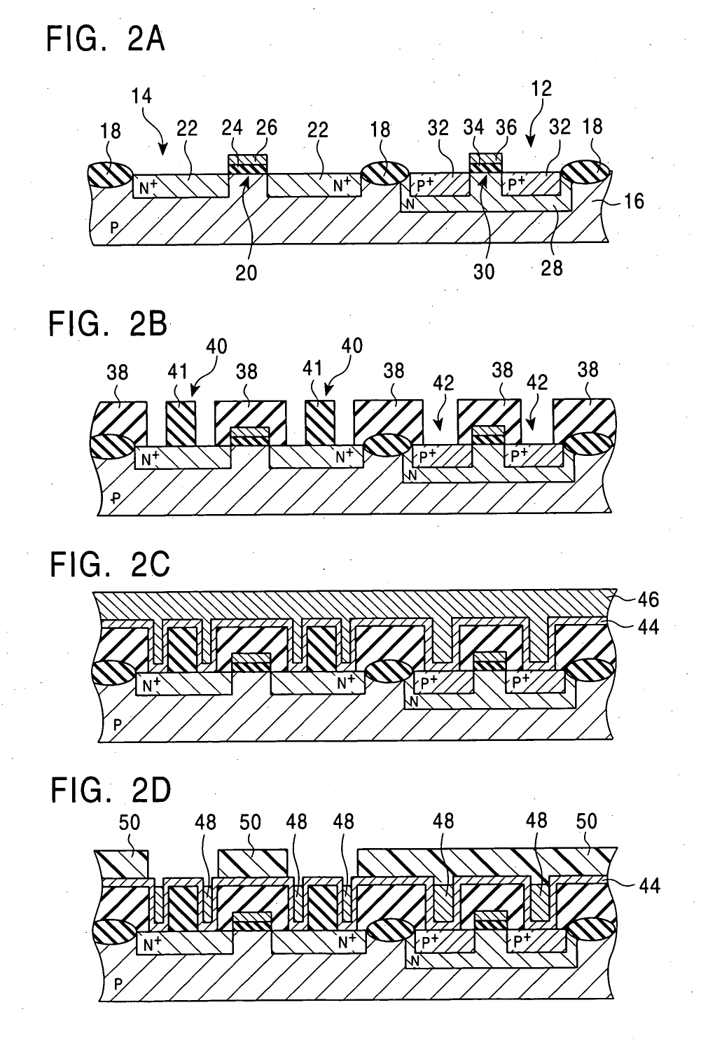

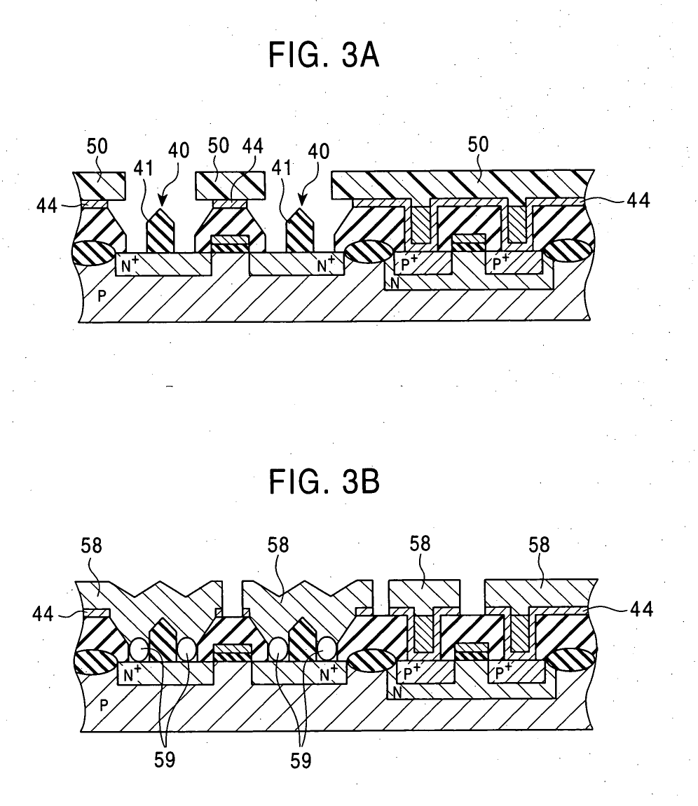

A method for manufacturing a semiconductor integrated circuit according to this invention will be described below with reference to the diagrams shown in FIGS. 2A-2D and FIGS. 3A-3B.

In the schematic sectional diagram of the layout shown in FIG. 2A, the right side is a device formation region in which the PMOS 12 used as an element for constructing various circuitry of the semiconductor integrated circuit is formed. The left side is a device formation region in which the NMOS 14 used as a Zener zap-type fuse device is formed. The device formation regions for the PMOS 12 and the NMOS 14 are isolated from each other with a LOCOS oxide film 18 on the surface of the P-type silicon substrate 16.

In the device formation region for the NMOS 14 serving as a fuse device, a gate electrode 26 is formed over the channel region 20 with a gate dielectric film 24 therebetween. Patterning a polysilicon film forms the gate electrode 26. Source and drain regions (N⁺-type diffusion regions) 22 are formed on either side of a channel region 20. The source and drain regions 22 are formed by ion implantation of N-type impurities, e.g., P (phosphorous) or As (arsenic), by using the gate electrode 26 as a mask. The gate electrode 26 and the source and drain regions 22 constitute the NMOS 14.

In the device formation region for the PMOS 12, a gate electrode 36 is provided over the channel region 30 with a gate dielectric film 34 therebetween. Source and drain regions (P⁺-type diffusion regions) 32 are formed on both sides of a channel region 30 by implantation of P-type impurities, e.g., B (boron), by using the gate electrode 36 as a mask.

The steps up to this point are carried out by the use of a standard CMOS semiconductor integrated circuit manufacturing process.

As shown in FIG. 2B, a silicon oxide film, e.g., a layered BPSG (boro-phospho-silicate glass)/NSG (non-doped silicate glass) film, is deposited to have a film thickness of about 1.2 μm over the entire surface of the silicon substrate 16, so as to form the interlayer insulating film 38. Preferably, a known oxide film CMP method or thermal reflow process is used to planarize the surface of the interlayer insulating film 38.

First contact holes 40 for the NMOS 14 serving as a fuse device and second contact holes 42 for the PMOS 12 serving as an element for various circuitry are formed in the corresponding portions of the interlayer insulating film 38. The formation of these contact holes may be made simultaneously with the use of known photolithography and etching technique. At this point, as shown in FIG. 2B, columnar insulator regions 41 are formed by leaving the interlayer insulating film 38 in the central portions in the first contact holes 40 for the NMOS 14.

After the first and second contact holes 40 and 42 are formed, as shown in FIG. 2C, for example, a 15 nm thick Ti film and a 150 nm thick TiN film are sputtered in that order over the entire surface of the silicon substrate 16, so that a barrier metal layer 44 is formed over the interlayer insulating film 38 and on inner surfaces of the first and second contact holes 40 and 42.

Subsequently, a tungsten film 46 of about 600 to 800 nm in thickness is formed by a CVD method using a WF₆-H₂-based source gas over the barrier metal layer 44 including the inside of the first and second contact holes 40 and 42. The thickness of the tungsten film is sufficient to completely, or at least substantially, fill the first and the second contact holes 40 and 42.

As shown in FIG. 2D, the tungsten film 46 over the surface of the interlayer insulating film 38 is polished and removed by a metal CMP method. At this point, the barrier metal layer is left by the use of a known endpoint detection means. In this manner, tungsten plugs 48 are formed in the first and second contact holes 40 and 42.

A photoresist film is formed over the entire surface of the silicon substrate 16, and is patterned, so that the resist pattern 50 exposes the portions over the first contact holes. However, as shown in FIG. 3A, the resist pattern 50 covers the remaining portions of the surface including portions above the second contact holes 42.

As shown in FIG. 3A, isotropic etching is carried out using H₂O₂ (hydrogen peroxide) and BHF (buffered hydrofluoric acid) solutions so as to selectively remove the tungsten plugs 48 and the barrier metal layer 44 from the inside of the first contact holes 40. Also, the sidewall of the first contact hole is isotropically etched to form a taper. In addition, the heads of the columnar insulator regions 41 are also isotropically etched to decrease the height of the insulating regions 41 and to form a taper at the tops of the columnar insulator regions 41.

As shown in FIG. 3B, after the photoresist film 50 is removed, an AlCu alloy film is formed by sputtering. Electrodes 58 are then formed using a known patterning process. At this point, the barrier metal layer 44 is simultaneously patterned, and wirings composed of laminated AlCu film 58 and barrier layer 44 are formed on the surface of the interlayer insulating film 38.

As shown in FIG. 3B, the AlCu film having an excellent coverage is formed at the upper portion of the first contact holes 40. On the other hand, at the bottom of the first contact holes 40, voids 59, where no wiring material is present, are formed.

In this manner, the insulator regions 41 reduce the contact areas between the electrodes 58 and the semiconductor regions (the source and drain regions 22) in the first contact holes 40. Consequently, the initial yield of the fuse device can be significantly improved. Furthermore, the upper portion of the first contact holes 40 can be tapered or rounded. Consequently, the AlCu alloy film is adequately formed with a high coverage and, therefore, there is an adequate supply source of Al atoms to form the Al filament.

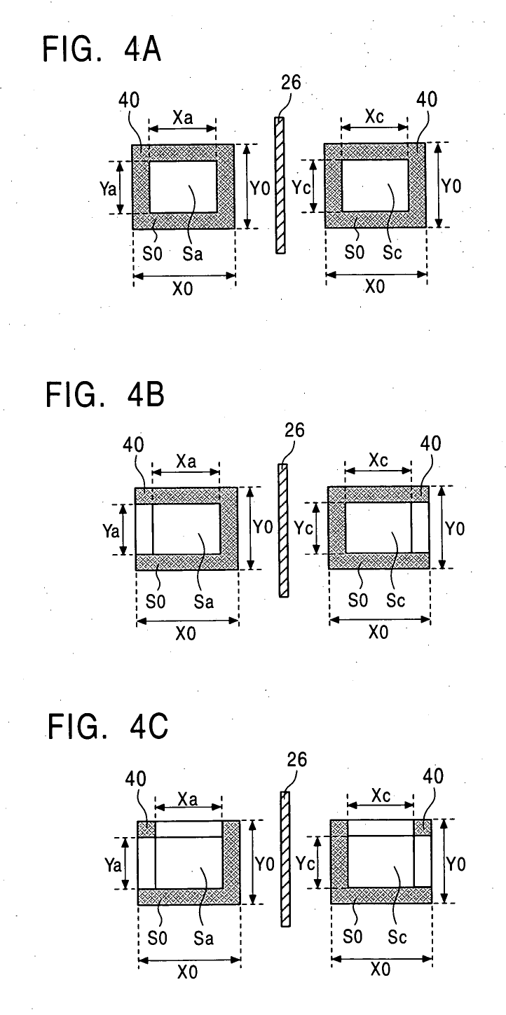

Next, the first contact holes 40 will be further described with reference to FIGS. 4A-4C. Each of FIGS. 4A-4C is a plan view schematically showing the shapes of the bottoms of the first contact holes 40 on both sides of the gate electrode 26. In each figure, the shaded portions in the perimeters of the contact holes 40 are portions at which the surfaces of the source and drain regions 22 are exposed. That is, the insulator regions 41 are formed over portions other than the shaded portions.

In the following description, as shown in FIG. 4A, the size of the bottom of the first contact holes 40 is represented by X0 and Y0, the size of the bottom of the insulator region 41 in the source side contact hole 40 is represented by Xa and Ya, and the size of the bottom of the insulator region 41 in the drain side contact hole 40 is represented by Xc and Yc.

The area of the bottom of the first contact hole 40, including the area covered by the insulator region 41, is represented by S0=X0×Y0. The area of the bottom of the insulator region 41 in the source side contact hole is represented by Sa=Xa×Ya, and the area of the bottom of the insulator region 41 in the drain side contact hole 40 is represented by Sc=Xc×Yc.

Here, preferably, the size X0 and Y0 of the bottom of the first contact hole 40 is X0=Y0=0.25 to 2.0 μm. Also preferably, a ratio of the area where no insulator region 41 exists, that is, the area where the electrode 58 contacts the source or drain region 22 provided in the semiconductor substrate 16, to the total area of the bottom of the contact hole 40 is within a range of 1×Sa/S0=1−Sc/S0=0.2 to 0.5.

In this manner, the contact area between the electrode 58 and the source or drain region 22, which is provided in the surface of the semiconductor substrate 16, is made smaller than the area of the bottom of the first contact hole 40. Consequently, the density of current for programming can be locally increased and, thereby, the programming characteristic of the fuse device can be improved.

Further, the contact between the electrode 58 and the source or drain region 22, which is provided in the surface of the semiconductor substrate 16, is made only at the area reduced by the above-described ratio. Consequently, the generation of spike of the wiring material in the semiconductor substrate 16 is suppressed.

When the height of the first contact hole 40 (the thickness of the interlayer insulating film 38) is represented by H0, the height Ha of the top end of the insulator region 41 is preferably set to be Ha≦(⅔)×H0.

The insulator regions 41 is not necessarily formed in the central portion of the first contact holes 40 separately from the interlayer insulating film 38. For example, as shown in FIG. 4B, the insulator region 41 extends on one side, and is connected to the interlayer insulating film 38. As shown in FIG. 4C, the insulator region 41 extends and connects with the interlayer insulating film 38 on two sides.

A resist pattern, although not shown in the drawing, is used for forming the first contact holes 40 shown in FIG. 2B. In the resist pattern, portions for forming the insulator regions 41 have very small dimensions and, therefore, may readily be peeled off. However, the peeling off can be prevented when this portion of the resist pattern is not isolated, i.e., is connected to the resist pattern covering the outside of the contact holes 40 on at least one side.

The contact holes 40 taking the shape schematically shown in FIG. 4B or 4C can be formed by a process using such a resist pattern.

The arrangement of the insulator region 41 is not limited to the examples shown in the drawings, and any arrangement in the contact holes 40 may be adopted.

In the embodiment described above, the tungsten plug 48 and the barrier metal layer 44 in the first contact holes 40 are removed by wet etching using H₂O₂ and BHF solutions. However, they may also be removed by plasma etching using an etching gas containing SF₆, for example.

Plasma etching using an etching gas containing CF₄, for example, may also carry out the taper etching of the interlayer insulating film 38 at the contour of the first contact hole 40 and the head of the insulator region 41.

In the above-described embodiment, both the first contact holes 40 and the second contact holes 42 are formed, and both are filled with the barrier metal layer 44 and the tungsten plug 48. Thereafter, the tungsten plug 48 and the barrier metal layer 44 in the first contact holes 40 are removed.

However, according to various exemplary embodiments, it is also possible that only the second contact holes 42 are formed and filled with the barrier metal layer 44 and the tungsten plug 48. Thereafter, a resist pattern for forming the first contact holes 40 is formed. A wet or dry isotropic etching and then an anisotropic etching form the first contact holes 40, which are tapered in the upper portion and include the insulator region 41.

In this case, in order to prevent or reduce the peeling off of the resist pattern of the portion corresponding to the insulator region 41 during the isotropic etching, preferably, at least one side thereof is connected to the resist pattern covering the outside of the contact holes 40.

In the semiconductor integrated circuit according to this invention, not only the silicon substrate, but also various other previously known semiconductor substrates can be used.

The fuse device capable of being programmed between a non-conductive state and a conductive state may be a MOSFET, e.g., NMOS and/or PMOS, as in the above-described embodiment, or a diode. That is, the fuse device is essentially a device having a PN junction formed in a semiconductor region that can be destroyed by the intrusion of a flowable metal from an electrode.

The fuse device is formed, at least partly, in a semiconductor region on a surface of a semiconductor substrate. Specifically, in the embodiment described above, the PN junction of the fuse device (the NMOS 14) is formed in a semiconductor region (the device formation region), which is a surface portion of the semiconductor substrate 16 itself.

However, it is also possible to form the fuse device in a semiconductor region provided separately from and over the surface of the semiconductor substrate. For example, a diode, or the like, formed in a polysilicon layer provided on an insulating film over a surface of a semiconductor substrate may also be used as a fuse device.

Any semiconductor devices may be formed on the same semiconductor substrate, in addition to the fuse device, to construct the semiconductor integrated circuit.

The plug filled in the contact hole is not limited to the tungsten plug. Any known refractory metal plugs can be used.

The plug is preferably formed by depositing a film of refractory metal in the contact hole and on the interlayer insulating film, and then removing the portion deposited on the interlayer insulating film by CMP, as in the above-described embodiment. However, the plug may be formed by other known methods. For example, the plug may be formed by an etch back using plasma etching.

The electrode material is not limited to the AlCu alloy. When aluminum is used as the flowable metal, the electrode can be formed by pure Al, and by other various Al alloys. However, in order to increase the reliability of the wiring, as described above, the electrode is preferably formed from an aluminum or aluminum alloy film that contains essentially no Si. That is, it is preferable to use an aluminum or aluminum alloy that contains no Si or contains Si at a low content, within a range in which no Si nodule is generated in narrow wirings.

Besides aluminum, as disclosed in, for example, U.S. Pat. No. 5,019,878, metals which form silicide, e.g., titanium, can be used as the flowable metal. Metals such as gold, copper, silver, and the like can also be used as the flowable metal.

A semiconductor integrated circuit according to this invention and methods for manufacturing the same have been described in detail. The present invention is not limited to the above-described embodiment. As a matter of course, improvements and modifications may be performed within the spirit and scope of the present invention.

What is claimed is:

1. A method for manufacturing a semiconductor integrated circuit comprising:
providing a semiconductor substrate having a fuse device present at least partly in a semiconductor region on or over a surface of the semiconductor substrate;
forming an interlayer insulating film over the surface of the semiconductor substrate, the interlayer insulating film having a top surface;
forming a contact hole in the interlayer insulating film over the semiconductor region such that a columnar insulator region having a top end lower than the top surface of the interlayer insulating film is formed in a central portion of the contact hole; and
forming an electrode in the contact hole such that the electrode contacts the semiconductor region at a periphery of a bottom of the contact hole where the columnar insulator region is not formed.

2. The method according to claim 1, wherein the forming of the contact hole includes:
removing the interlayer insulating film from the periphery of the contact hole while leaving the interlayer insulating film at the central portion of the contact hole;
forming a mask over the interlayer insulating film that exposes the contact hole; and
isotropically etching, through the mask, the interlayer insulating film left at the central portion of the contact hole to make the columnar insulator region have a tapered head with the top end lower than of the top surface of the interlayer insulating film.

3. The method according to claim 2, wherein the isotropically etching further etches the interlayer insulating film around a perimeter of the contact hole to taper the contour of the contact hole.

4. The method according to claim 1, wherein:
the providing of the semiconductor substrate provides the semiconductor substrate further having a second device formed in a second semiconductor region on or over the surface of the semiconductor substrate;
the forming of the contact hole further includes forming a second contact hole in the interlayer insulating film over the second semiconductor region, forming plugs in the contact hole and in the second contact hole and selectively removing the plug from the contact hole; and
the forming of the electrode further includes forming a second electrode that contacts the second semiconductor region via the plug.

5. The method according to claim 4, wherein the forming of the electrode further includes forming a metal film over the interlayer insulating film and patterning the metal film to form the electrode and the second electrode.

6. The method according to claim 1, wherein, within the contact hole, a ratio of an area where the insulator region does not exist to a total area of the bottom of the contact hole is within a range of from about 0.2 to about 0.5.

7. A semiconductor integrated circuit comprising:
a semiconductor substrate having a fuse device present at least partly in a semiconductor region on or over a surface of the semiconductor substrate;
an interlayer insulating film covering the surface of the semiconductor substrate, the interlayer insulating film having a top surface and a contact hole over the semiconductor region, a central portion of the contact hole having a columnar insulator region having a top end lower than the top surface of the interlayer insulating film; and
an electrode that contacts the semiconductor region at a periphery of a bottom of the contact hole.

8. The semiconductor integrated circuit according to claim 7, wherein the electrode is formed of a film primarily composed of a flowable metal that flows into the semiconductor region through an interface at the bottom of the contact hole.

9. The semiconductor integrated circuit according to claim 7, wherein the electrode is made of a film of aluminum or an aluminum alloy containing substantially no silicon.

10. The semiconductor integrated circuit according to claim 7, wherein a contour of the contact hole and a head of the insulator region are tapered.

11. The semiconductor integrated circuit according to claim 7, wherein the columnar insulator region in the contact hole is connected to the interlayer insulating film at at least one sidewall of the contact hole.

12. The semiconductor integrated circuit according to claim 7, wherein:
the semiconductor substrate further has a second device formed in a second semiconductor region on or over the surface of the semiconductor substrate;
the interlayer insulating film further has a second contact hole over the second semiconductor region, the second contact hole being filled with a plug; and
the electrode further includes a second electrode that contacts the second semiconductor region via the plug.

13. The semiconductor integrated circuit according to claim 7, wherein, within the contact hole, a ratio of an area where the insulator region does not exist to a total area of the bottom of the contact hole is within a range of from about 0.2 to about 0.5.

14. A method of manufacturing a semiconductor integrated circuit comprising:
providing a semiconductor substrate having a fuse device present at least partly in a semiconductor region on or over a surface of the semiconductor substrate;
forming an interlayer insulating film over the surface of the semiconductor substrate, the interlayer insulating film having a top surface;
forming a contact hole in the interlayer insulating film over the semiconductor region; and
forming a film of an electrode material in the contact hole to form an electrode that contacts the semiconductor region at a bottom of the contact hole,
wherein the forming of the contact hole and the forming of the film of electrode material in the contact hole further includes:
reducing a contact area between the electrode and the semiconductor region by forming a columnar insulator region at a central portion of the contact hole; and
increasing an amount of the electrode material in the contact hole by making a top end of the columnar insulator region lower than the top surface of the interlayer insulating film.

15. The method according to claim 14, wherein the forming of the film of electrode material in the contact hole further includes further increasing the amount of electrode material in the contact hole by tapering a head of the insulator region and a contour of the contact hole.

16. The method according to claim 14, wherein, within the contact hole, a ratio of an area where the insulator region does not exist to a total area of the bottom of the contact hole is within a range of from about 0.2 to about 0.5.
